(19) United States
(12) Patent Application Publication
(10) Pub. No.: US 2016/0305154 A1
(43) Pub. Date: Oct. 20, 2016

(54) Display Assembly As A Door Handle In An OEM Factory Construction, With A Cable Conduit

(71) Applicant: Wild August LLC, Deer Park, IL (US)

(72) Inventor: Larry English, Deer Park, IL (US)

(21) Appl. No.: 14/690,271

(22) Filed: Apr. 17, 2015

(51) Int. Cl. E05B 1/00; G08B 21/18; H05K 5/02; H05K 5/00; H03K 17/945

(52) U.S. Cl. CPC E05B 1/0084; H05K 5/0017; H03K 17/945; H05K 5/0204; G08B 21/18; E05B 1/0015

(57) ABSTRACT

An OEM factory install door handle construction comprising a display advertisement insert for a storage unit (e.g., a cooler) door is described. The construction is designed to interoperate with a storage unit's electrical system. Electrical wiring is passed from the storage unit, through standoff extrusions and into a display assembly. The standoffs allow the wiring from a storage unit to go through the center of the door handle and corresponding display assembly, via the standoff's center hole hollow core. The electrically-capable display assembly can be constructed with modules for lighting, audio, scent, as well as paper ads or for product pricing communication. Factory installation of the display assembly door handle prior to shipment saves time, and allows the display ad handle to be compatible with various manufacturer-specific door constructions.

### TECHNICAL FIELD OF THE INVENTION

The present invention relates generally to display advertising surfaces, and more specifically to door handle assemblies that are originally manufactured as a factory install.

### BACKGROUND OF THE INVENTION

U.S. patent application Ser. No. 13/540,534 to Larry English, which applicant hereby incorporates by reference, describes a display assembly that does not require replacement of a cooler door handle. As described, the display assembly allows advertisements to receive consumer attention at or near the moment of purchase, and allows for quick and easy advertisement changes. The invention of the '534 application overcomes the prior art in part because it enables the display assembly to be installed on a wide variety of existing legacy cooler door handles, rather that it being an Original Equipment Manufacturer (OEM) part or a full handle replacement. However, it would be advantageous to have an OEM display assembly door handle that can include features and conveniences not possible in a legacy-handle accessory. Another application, namely U.S. patent application Ser. No. 13/570,011, hereby incorporated by reference, describes a door handle display assembly capable of generating multisensory stimuli when a person approaches the handle. For example, it describes a motion or proximity sensing device, physically coupled to the surface of the display assembly, and at least one lighting device electrically coupled to the motion or proximity sensing device. The present invention advantageously incorporates these features while being an OEM factory door handle installation, which allows for synergies not possible to realize in the '011 embodiments.

As one example, an OEM factory install display assembly door handle is designed to interoperate with a cooler's electrical system. It is able to be used with modules for lighting, audio, scent, as well as paper ads or for product pricing communication.

U.S. Pat. No. 7,383,654 to Olivier et al. (“Olivier”) describes an apparatus and method for providing a door handle adapted to receive interchangeable display inserts. Olivier describes a handle body having a securable portion and graspable portion, together with a support surface for receiving a display insert. However, Olivier does not describe placement of a display surface as a door handle in an OEM factory construction with a cable chase or conduit, specifically designed to interoperate with a cooler's electrical system, constructed with attachment standoffs as will be described below.

### SUMMARY OF THE INVENTION

This invention is an OEM factory construction door handle comprising a display advertisement insert, though the teachings herein may apply equally to retrofits. The door handle is designed to interoperate with a cooler's electrical system. The handle can be used with modules for lighting, audio, scent, as well as paper ads or for product pricing communication. It comprises a display assembly, a handle foundation, and standoffs (of different shapes, preferably either oval or diamond) having mounting holes and a center hole hollow core, through which electrical wiring passes from the cooler all the way to the handle itself. The display assembly comprises a convexly curved surface. When one of the display assembly's end caps is removed (e.g., the top), a display ad and its optional clear flexible cover are inserted. Because the advertisement is at the handle, a customer's attention is easily drawn to the ad. The invention can be used with any type of storage unit, not just for doors of refrigerated coolers or freezers.

### BRIEF DESCRIPTION OF THE DRAWINGS

FIG. 1 is an installed factory OEM door handle assembly.

FIG. 2 is a close-up view of an installed OEM door handle assembly.

FIG. 3 is an oval/racetrack shaped standoff.

FIG. 4 is a perspective view of a broader diamond shaped standoff.

FIG. 5 is a top view of a broader diamond shaped standoff.

FIG. 6 is a side view of a broader diamond shaped standoff.

FIG. 7 is a front view of a display assembly.

FIG. 8 is a rear view of a display assembly.

FIG. 9 is a top-side view of a display assembly.

FIG. 10 is a side view of a display assembly.

FIG. 11 is an exploded view of a standoff display assembly.

FIG. 12 is a side view of a standoff display assembly.

FIG. 13 is a top-side view of a standoff display assembly.

### DETAILED DESCRIPTION OF INVENTION

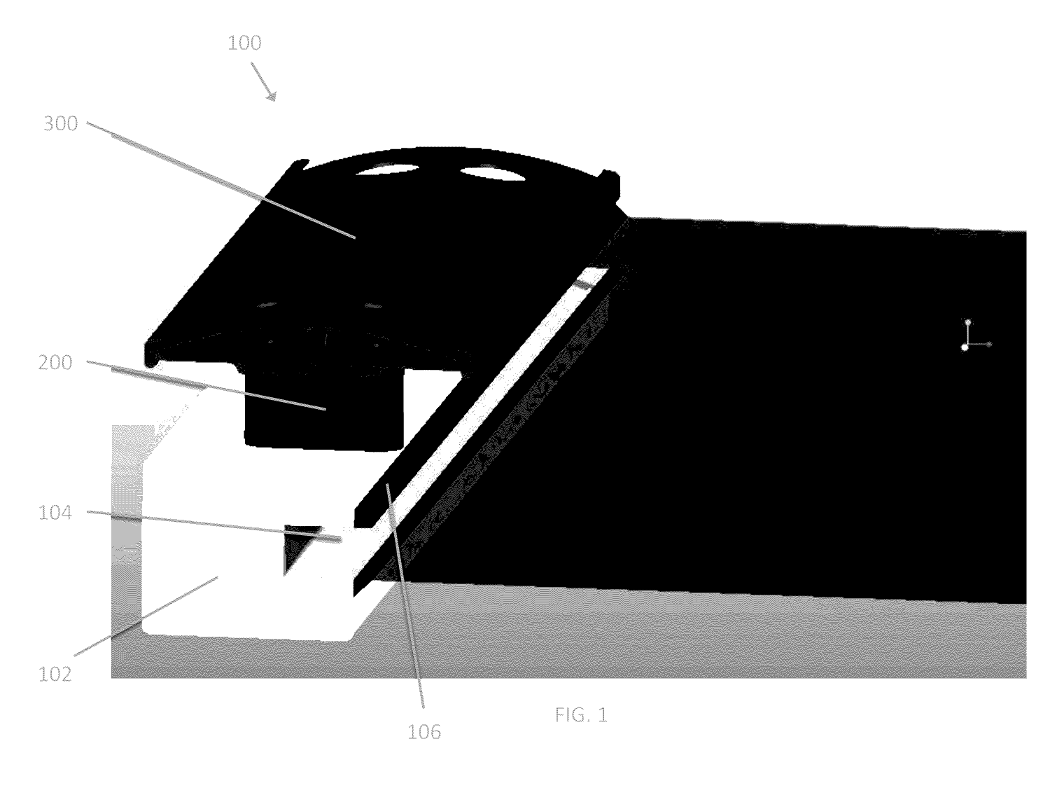

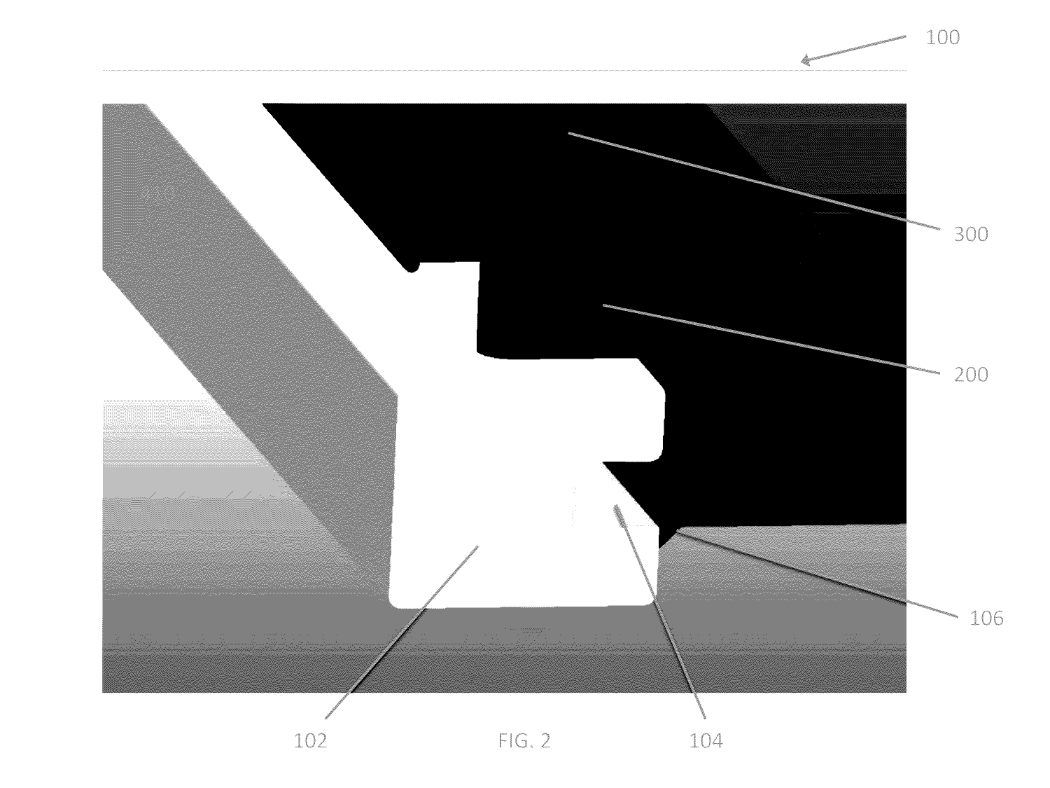

FIG. 1 shows a representative fully constructed OEM factory install door handle display assembly 100. It comprises a display assembly 300 to receive an advertisement insert, and an oval shaped standoff 200, which facilitates the attachment of the display assembly 300 to the door handle 102. The door handle 102 itself comprises a canal 104 to accommodate the door, and a fastener 106 to allow a secure connection between the door handle 104 and the door. The OEM factory install assembly 100 is designed to interoperate with the cooler door's electrical system. A transformer (not shown) resides within the cooler, and wiring is passed through the door and door handle through the standoff 200 and into the display assembly 300. This allows it to be used with modules for lighting, audio, scent, as well as paper ads or for product pricing communication (instead of little price tags in coolers). Therefore the assembly 100 acts as a cable conduit. FIG. 2 is a close-up view of the OEM factory install door handle display assembly 100.

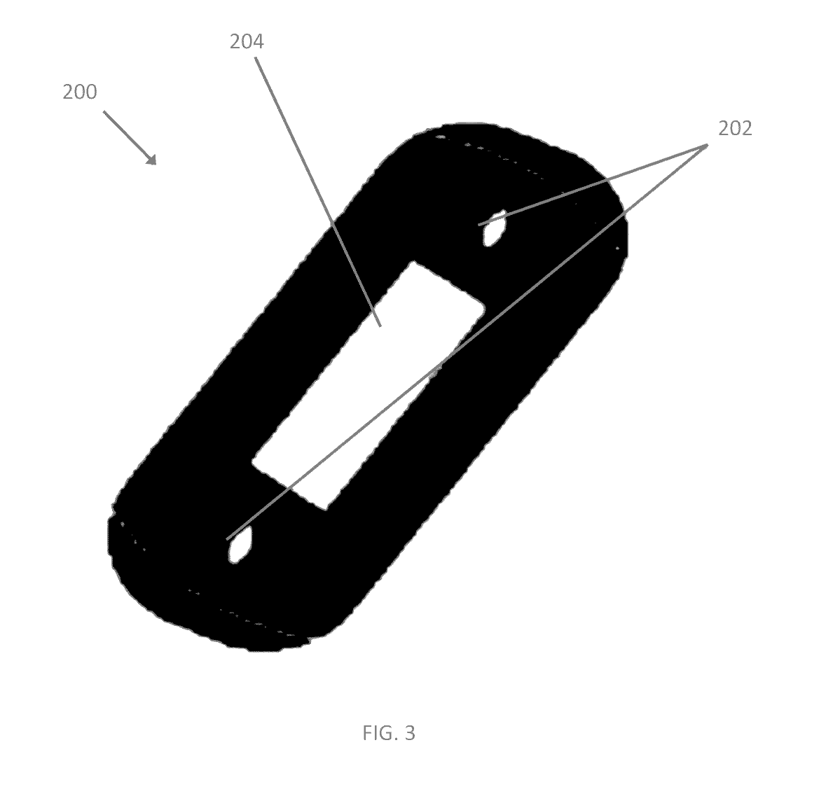

FIG. 3 shows a close-up view of an oval/racetrack shaped standoff 200 used in the constructions of FIGS. 1 and 2. It consists of mounting holes 202 and a center hole hollow core 204. This standoff 200 is preferably either an aluminum extrusion or a polymer casting molding. The standoffs 200 allow the wiring from a cooler to go through the center of the door handle and corresponding display assembly, via the standoff's center hole hollow core 204. The standoffs are connected to a cooler door from its handle through the small mounting holes 202 in the standoff and into inserts in the cooler door or from the back of a cooler door, through the standoffs and into female threaded inserts in a door handle. Wiring is then passed through the large center hole hollow core 204 from the cooler into the handle, then just below the module where all final connections are accomplished. That is, the center hole hollow core 204 to this standoff 200 allow the cable/wire to pass through from the exterior of the door to the center of the standoff, through a hole into the cavity of the handle, and up to the electronic endcap, on the right side.

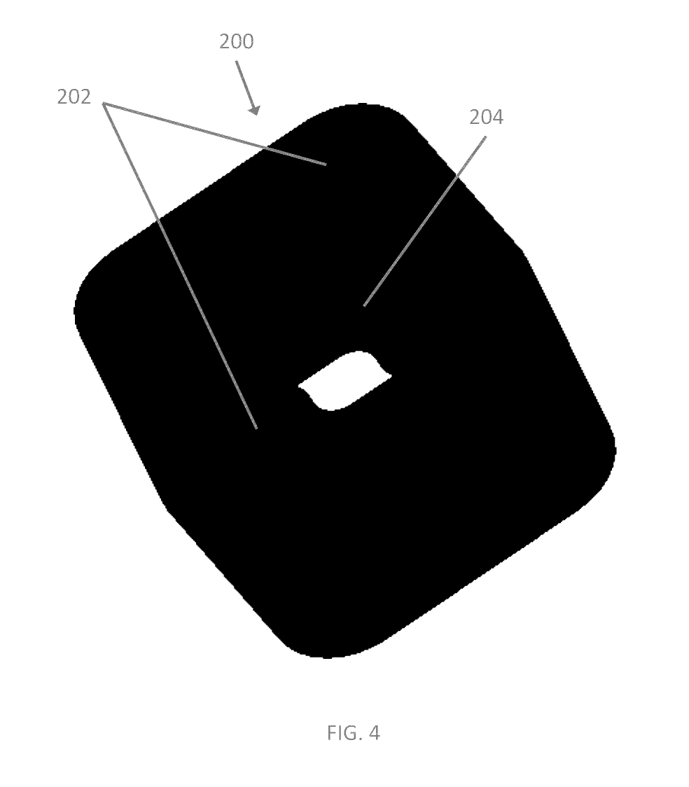

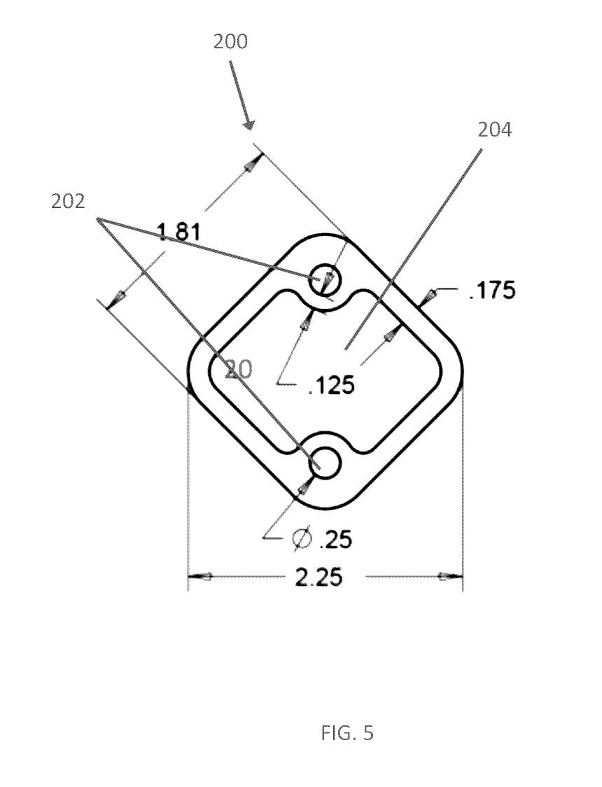

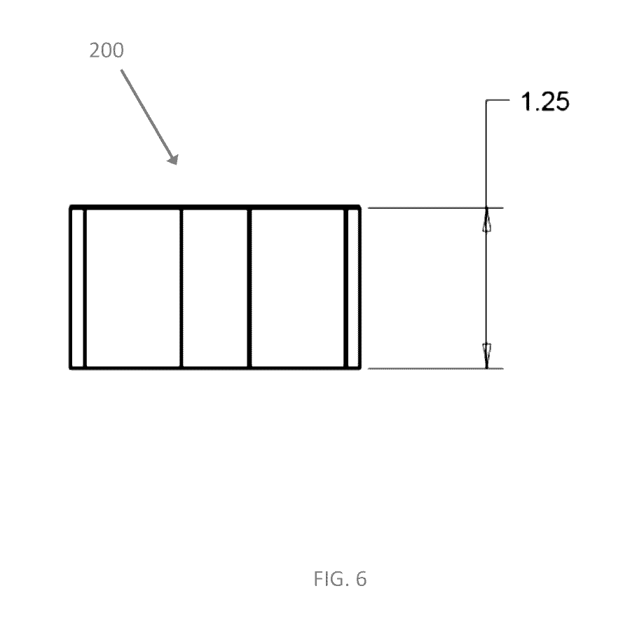

FIG. 4 is a perspective view of a broader diamond shaped standoff 200. It similarly comprises mounting holes 202 and a center hole hollow core 204, and supports the same construction and functionality as that of the oval/racetrack standoff. That is, it allows wiring from a cooler to pass through such that various electronic features can be constructed within the assembly. FIG. 5 is a schematic view of a broader diamond shaped standoff 200 from the top. It shows the requisite dimensions suitable for accomplishing a factory install mounting of a display assembly to a door handle, though other dimensions are possible. Here as shown, the diameter of the mounting holes is 0.25 in, the main diamond path is 0.175 in, width 1.81 in, width around mounting holes 0.125 in, and length (corner to corner) 2.25 in. Preferably, the inside corners of some areas of the standoff extrusion are not sharp, and have fillets or rounds. Though, it is possible to design the standoff either way: with round fillets on their inside corners, or just keep the hidden edges sharp. FIG. 6 is a side view of the broader diamond shaped standoff 200, illustrating its relative dimensions in one embodiment. FIG. 6 shows that the diamond standoff here is slightly more long than wide. The holes 202 on the extrusion do not necessarily have to be centered on its thickened portion, as they can be offset a bit. However, the line of holes can be centered, on its thicker portion, in variations, to get the most support. Additionally, the thicker portion of the standoff can be wider, or alternatively, the entire flat back area can be made thicker to eliminate or reduce the thickened portion.

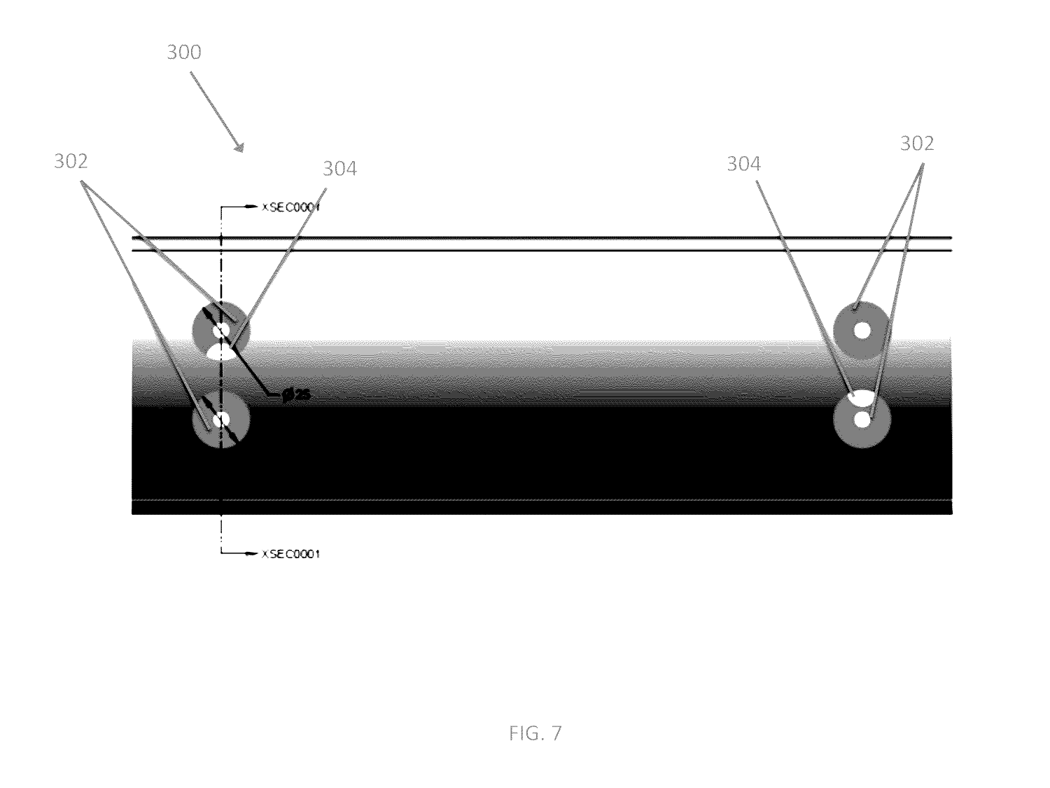

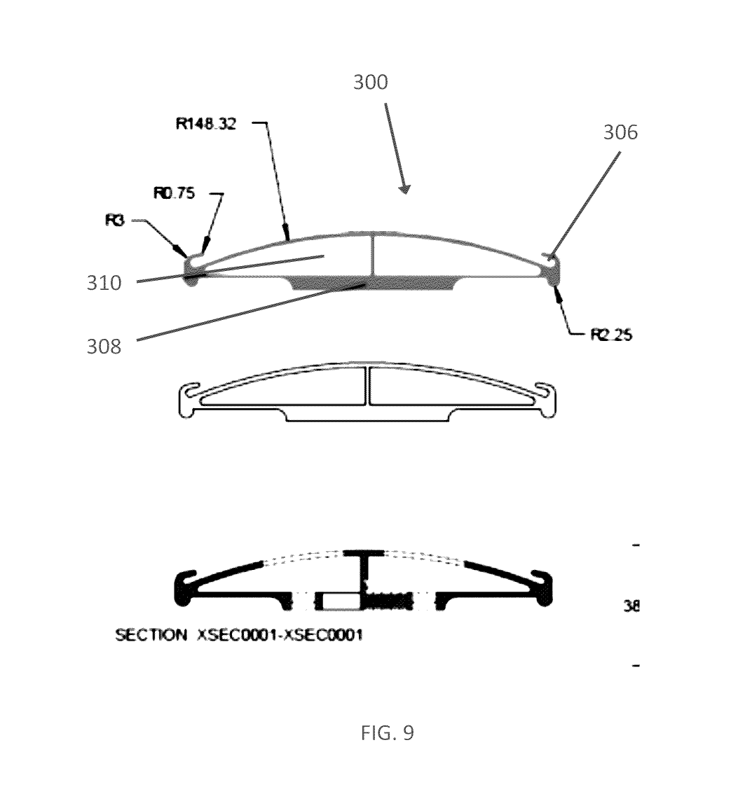

FIG. 7 illustrates a front view of the display assembly 300, minus any display insert. As can be seen, the display assembly is generally rectangular, and in this embodiment has a convexly curved surface. Along each side of the curved surface is a lip flange 306 (highlighted in FIG. 9). When one of the display assembly's end caps is removed (e.g., the top), a display ad and its optional clear flexible cover (e.g., of thin transparent plexiglass) may be inserted into the display assembly. The end cap is then replaced. The display ad is thereby held in by the lip flange and the respective end caps. FIG. 7 also shows apertures 302 (diameters 25 in each) for receiving fastening screws for various kinds of attachment brackets; as well as a partially obscured view of rear insertion holes 304 through which electrical wiring is passed.

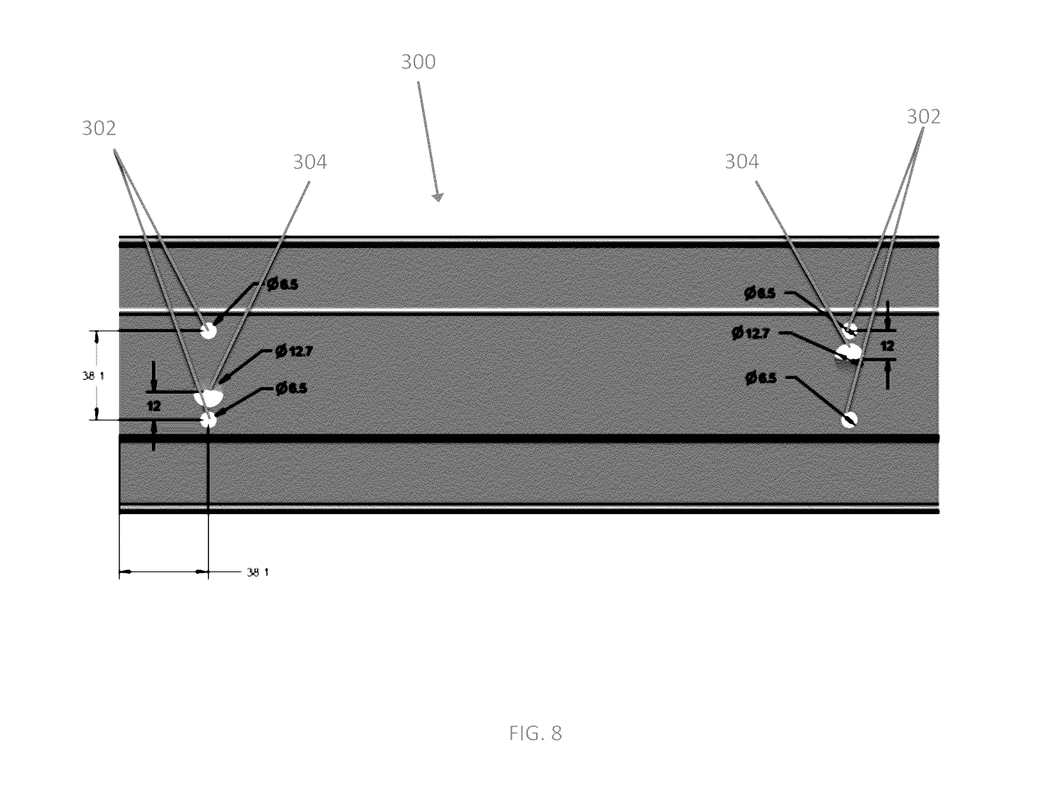

FIG. 8 is a rear view of a display assembly 300. As shown, it comprises a modified main handle cross-section and set of apertures 302 to accommodate the standoff 200, either the oval or diamond shaped standoff. Shown in full are the insertion holes 304 through which wiring passes via the standoffs from a cooler door. A base 308 is a slightly protruding segment of the main handle cross-section, protruding so as to facilitate the attachment to the handle foundation 102 via the standoffs 200.

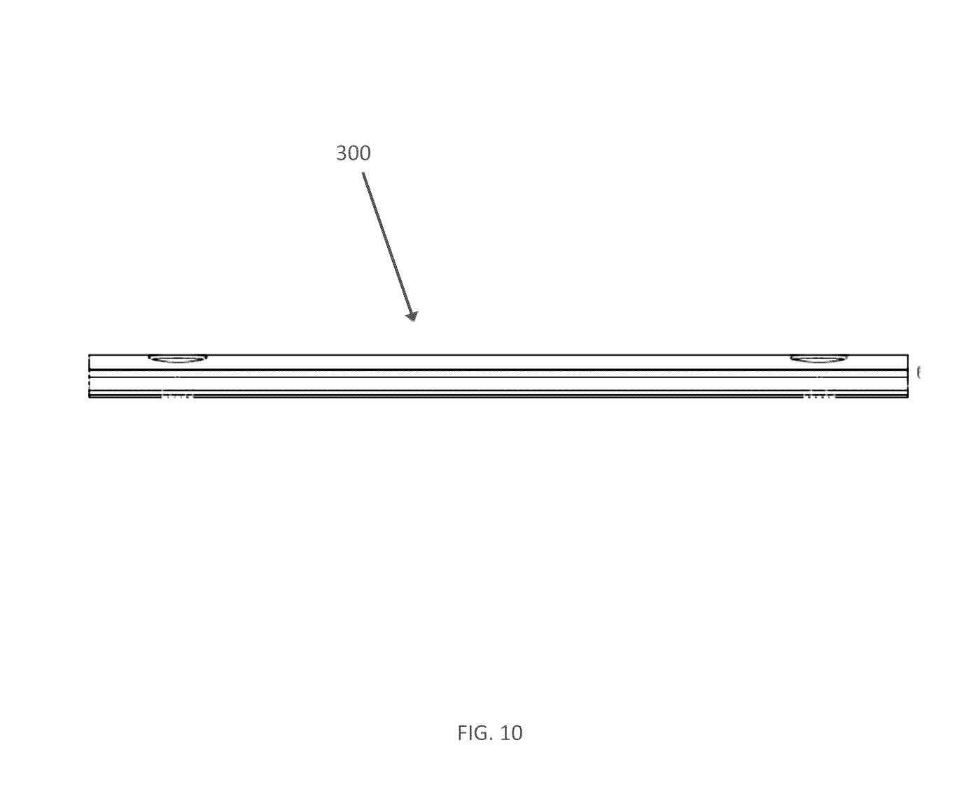

FIG. 9 is a top-side view of the display assembly 300. The base 308 serves as a mount, creating sufficient separation between the door handle and the display assembly. An end cap is placed on the end opening 310, fixing an advertisement display insert within the assembly. Further, the lip flange 306, together with the end caps, hold in the display ad. FIG. 10 is a side view of the display assembly 300.

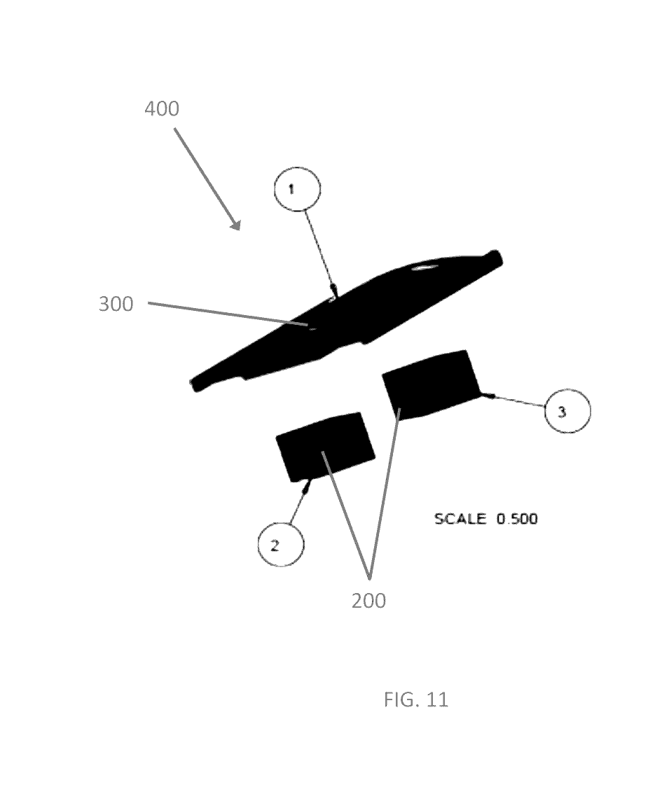

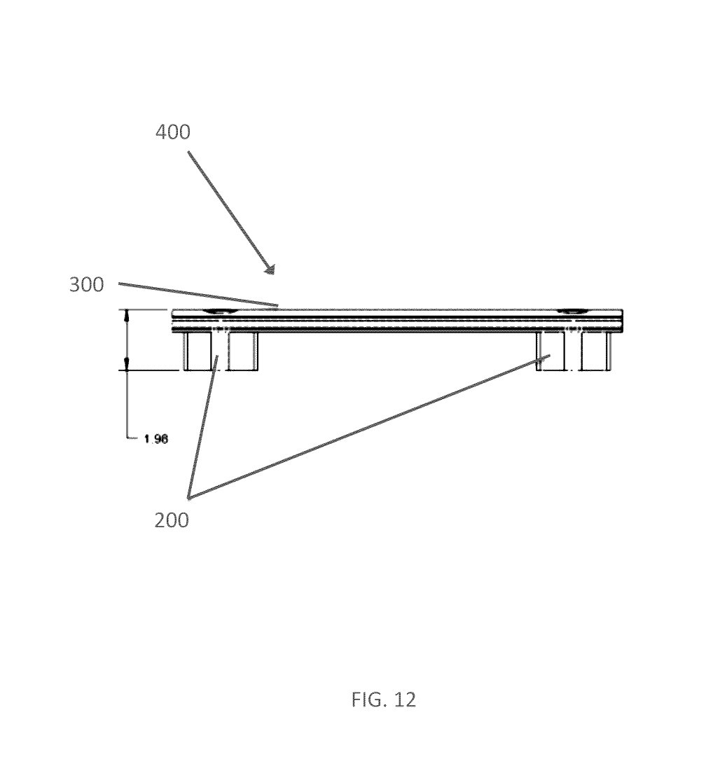

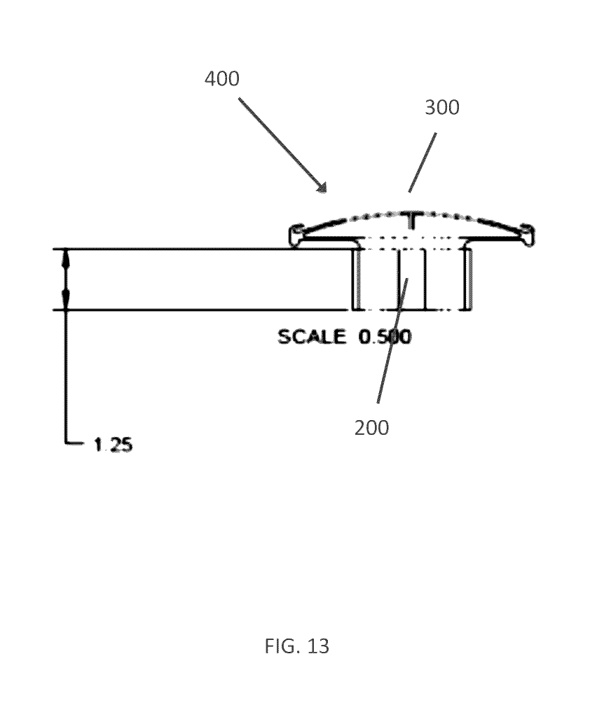

FIG. 11 is an exploded view of the display assembly 300 and its two diamond shaped standoffs 200, prior to assembly. The standoffs are attached to the rear of the display assembly through the apertures, via the mounting holes 202 of the standoffs. On the standoffs for the factory unit, there are 8 MM bolts and threaded inserts in the cooler doors to receive them. The standoffs should be mounted sideways to help prevent torque. The display assembly apertures 302 and door handle holes must be laid out similarly. A concave area of the display assembly can be flattened (referring to base 308) to provide sufficient room for mounting the standoffs. FIG. 12 shows the standoffs 200 connected to the display assembly 300. The height from the bottom of the standoffs to the outer surface of the display assembly is 1.96 in. FIG. 13 is top-side view of a standoff display assembly. The height of the standoff is 1.25 in.

The OEM door handle assembly 100 is specifically designed to interoperate with a cooler's electrical system. There is commonly a DC transformer inside the cooler to convert AC to DC voltage. The transformer could be 12V inside the cooler's electrical system, compatible with LEDs and customized modules. Many coolers use LED lighting strips to illuminate the edge of cooler glass.

While the above specification and examples provide a description of the invention, many embodiments of the invention can be made without departing from the spirit and scope of the invention. It is to be understood that the foregoing embodiments are provided as illustrative only, and does not limit or define the scope of the invention. Various other embodiments are also within the scope of the claims.

What is claimed is:

1. A door handle assembly that interoperates with a storage unit's electrical system comprising:
at least one standoff having mounting holes and a center hole hollow core;
a display assembly for receiving a display advertisement insert, the display assembly comprising apertures engaging with the core of the at least one standoff; and
at least one wire in electrical communication with the storage unit's electrical system that passes through the door and a door handle through the center hole hollow care of the standoff, then through the apertures and into the display assembly, to supply power to the display assembly.

2. The handle assembly of claim 1, wherein the assembly is constructed prior to shipment and is compatible with a storage unit's manufacturing characteristics.

3. The handle assembly of claim 1, wherein the storage unit comprises a DC transformer to convert AC to DC voltage.

4. The handle assembly of claim 1, wherein the at least one standoff is diamond shaped.

5. The handle assembly of claim 1, wherein the at least one standoff is oval shaped.

6. The handle assembly of claim 1, wherein the at least one standoff comprises round fillets on its inside corners.

7. The handle assembly of claim 1, wherein the mounting holes of the at least one standoff are offset from the center.

8. The handle assembly of claim 1, wherein the mounting holes of the at least one standoff are centered.

9. The handle assembly of claim 1, wherein the door to the storage unit comprises bolts and threaded inserts to receive the at least one standoff.

10. The handle assembly of claim 1, wherein the at least one standoff is mounted sideways to help prevent torque.

11. The handle assembly of claim 1, further comprising:
a motion or proximity sensing device, physically coupled to a surface of the display assembly, and
at least one lighting device electrically coupled to the motion or proximity sensing device,
whereby a person passing in front of the surface causes the lighting device to actuate.

12. The handle assembly of claim 1, further comprising:
a motion or proximity sensing device, physically coupled to a surface of the display assembly, and
at least one audio device electrically coupled to the motion or proximity sensing device,
whereby a person passing in front of the surface causes the audio device to actuate.

13. The handle assembly of claim 1, further comprising:
a motion or proximity sensing device, physically coupled to a surface of the display assembly, and
at least one fan device electrically coupled to the motion or proximity sensing device and positioned to blow air over any said insert within the receptacle,
whereby a person passing in front of the surface causes the fan device to actuate and distribute scent into the person's general area.

14. The handle assembly of claim 1, further comprising:
a motion or proximity sensing device, physically coupled to a surface of the display assembly, and
a plurality of lighting elements positioned on the surface to be sandwiched between the surface and any inserted graphical display, and electrically coupled to the motion or proximity sensing device,
whereby a person passing in front of the surface causes the plurality of lighting elements to actuate.

15. The handle assembly of claim 14, further comprising electronics that sequentially actuate selected ones of the plurality of lighting elements.
